(19) United States
(12) Patent Application Publication
(10) Pub. No.: US 2008/0311820 A1
(43) Pub. Date: Dec. 18, 2008

(54) Inflatable noisemaker

(76) Inventor: Richard Craig Murdock, Colleyville, TX (US)

Correspondence Address: WHITAKER, CHALK, SWINDLE & SAWYER, LLP, 3500 CITY CENTER TOWER II, 301 COMMERCE STREET, FORT WORTH, TX, 76102-4186, US

(21) Appl. No.: 11/820,132

(22) Filed: Jun. 18, 2007

(51) Int. Cl. A63H 3/06; H01H 21/00; H01L 29/861

(52) U.S. Cl. 446/220; 200/553; 362/612

(57) ABSTRACT

An inflatable noisemaker comprising a tubular envelope having first and second ends and constructed to enclose a gas under pressure. A sealable opening is disposed proximate the first end for inflating the envelope. An active light emitting module is enclosed within a transparent chamber disposed within the envelope and configured with an activation device. The active light emitting module may comprise first and second cells stacked in series polarity, a removable insulating strip disposed between the first and second cells, and a light emitting device (LED) having first and second leads coupled to respective negative and positive terminals of the stacked cells. A housing including a spring for biasing the LED, the cells, and the insulating strip together may be provided. In an alternate embodiment, a single cell and a switch may be used in the active light emitting module.

### BACKGROUND OF THE INVENTION

1. Field of the Invention

The present invention generally relates to inflatable amusement devices and more particularly to inflatable noisemakers having additional features such as illumination.

2. Description of the Prior Art

Inflatable noisemakers are known, including air-filled tubes that can be slapped against each other lengthwise, to create drum-like sounds. The sounds thus created may be used for acoustically signaling applause or other communication. Conventional noisemakers of this type include the so-called “BamBams®” marketed by www.bambams.com. One feature of the model GB101 BamBams® includes a 5″ Glow-Stick inserted in the BamBam tube. The Glow-Stick must be broken to activate the glow feature. The “ThunderStix®,” manufactured and marketed by Vonco Products, Inc., Lake Villa, Ill. 60046 (See also www.Vonco.com), features a self-sealing valve that seals upon completing its inflation by filling it with air in the manner of blowing up a balloon. Another example is the Inflatable Noisemaker described by Marc I. Epstein in U. S. Patent Application Publication No. 2004/0157525, which is characterized by incorporating pebbles within the noisemaker to enhance the loudness when two of the noisemakers are slapped together.

Of the known inflatable noisemakers, only the “BamBams®” model described above provides some form of illumination. However, this passive form of illumination typically lacks brightness, which has limited effectiveness except when the ambient illumination is very, very low. What is needed is an inflatable noisemaker having an internal illumination apparatus that provides a very bright tube of light that is highly visible, even in a brightly illuminated arena or auditorium. Such an illumination apparatus is preferably low in cost, simple to manufacture, and easy to use.

### SUMMARY OF THE INVENTION

Accordingly there is disclosed an inflatable noisemaker, comprising: a tubular envelope having first and second ends and constructed to enclose a gas under pressure and further having a sealable opening disposed proximate the first end for inflating the envelope; and an active light emitting module enclosed within a transparent chamber disposed within the envelope and configured with an activation device.

In another aspect, the active light emitting module comprises a battery, for example first and second cells stacked in series polarity, wherein the stacked cells have a negative terminal at one end and a positive terminal at the opposite end of the stacked cells; a removable insulating strip disposed between the first and second cells and extending laterally from the stacked cells; a light emitting device (LED) having first and second leads, wherein the first lead of the LED is coupled to a negative terminal of the stacked cells and the second lead is coupled to a positive terminal of the stacked cells; and a housing including a spring for biasing the LED, the cells, and the insulating strip together.

### BRIEF DESCRIPTION OF THE DRAWINGS

FIG. 1 illustrates an illuminated noisemaker according to one embodiment of the present invention;

FIG. 2 illustrates an enlarged view of a first end of the embodiment of FIG. 1 depicting structures of the inflating mechanism;

FIG. 3 illustrates an enlarged view of a second end of the embodiment of FIG. 1 depicting structures of the illuminating mechanism;

FIG. 4 illustrates a cross section view of the second end of the embodiment of FIG. 3 taken along the line IV-IV;

FIG. 5 illustrates a pictorial circuit diagram of one embodiment of an active light emitting module for use in the embodiment of FIG. 1;

FIG. 6 illustrates a pictorial diagram of the one embodiment of the active light emitting module shown in FIG. 5; and

FIG. 7 illustrates a circuit diagram of an alternate embodiment of an active light emitting module for use in the embodiment of FIG. 1.

### DETAILED DESCRIPTION OF THE INVENTION

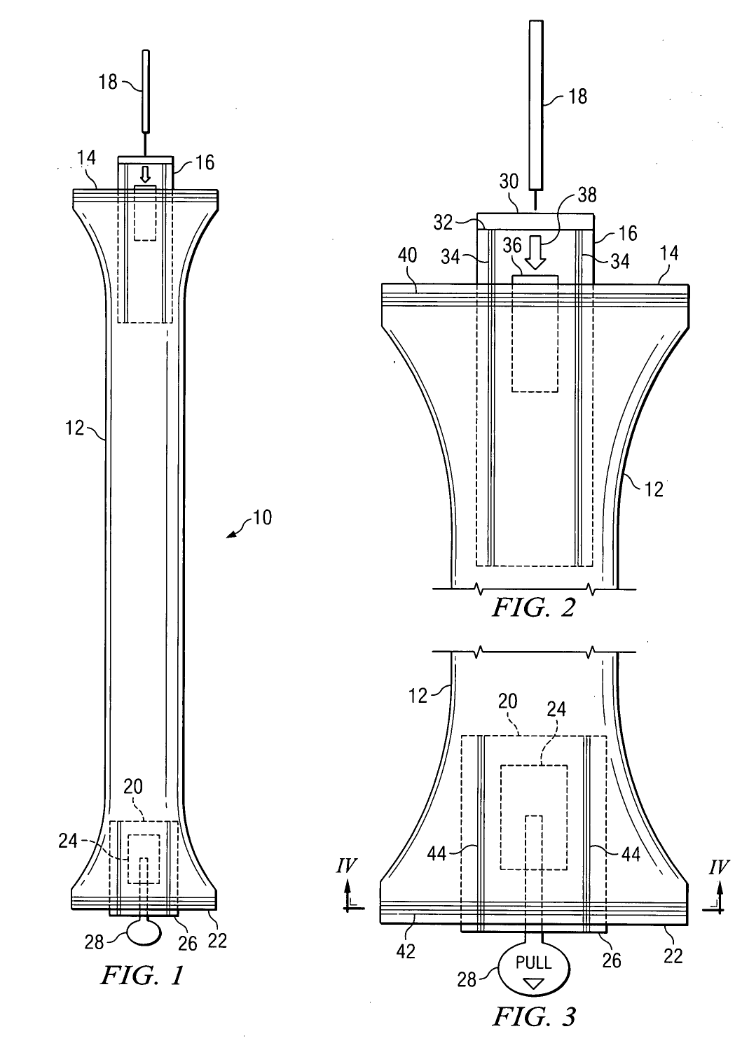

In the following description structures identified with the same reference numbers in several figures refer to the same structures appearing in the differing views. Referring to FIG. 1 there is illustrated an illuminated noisemaker 10 according to one embodiment of the present invention. A tubular envelope 12 for enclosing a gas under slight pressure and fabricated of a plastic membrane approximately 1 to 5 mils thick, is defined by a first end 14 and a second end 22. The envelope 12 of the described embodiment may typically be approximately 24 inches long and approximately 3 inches in diameter when inflated, although a wide range of dimensions are possible for use with the present invention. The envelope 12 may be supplied in pairs, each in a deflated state, generally folded, and enclosed in a small package (not shown). After removal from the package, inflation is accomplished by blowing through the gas passage of an inflation device or valve 16 incorporated into the first end of the envelope 12 until the envelope 12 is filled with air. Although the valve 16 as described below is the preferred embodiment of the inflation device, other inflation devices such as a re-sealable tube or a re-sealable check valve may also be used with the present invention. One example of the re-sealable check valve is the type of valve that is used for inflating vehicle tires, inflatable toys, and the like.

In the present invention, the valve 16 may, for example, be a small, flat, elongated envelope fabricated of polyethylene film approximately 1 to 2 mils thick, or a similar material and thickness may be used. The valve, which may be approximately 3 inches long, is positioned with about one third of its length extending from the first end of the envelope 12, the remaining length extending into the envelope 12. The valve 16 is retained in position at a defined portion of the first end of the envelope 12 by a hot press seal applied to the end 14 of the envelope 12. The hot press seal, which also defines the border of the envelope 12 at the first end, is shown at reference number 40 in FIG. 2 to be described hereinbelow. Further, the valve 16, being flexible and configured as a flat envelope, becomes self-sealing when the air pressure within the envelope 12 exceeds the ambient air pressure. In this way the envelope 12 and the valve 16 are sealed automatically at the same time. Further, squeezing the external portion of the valve 16 between the thumb and forefinger may also function to ensure that the valve is sealed. A removable tube or straw 18 may be supplied in the package to facilitate inflating the envelope 12 by inserting the straw 18 through the gas passage of the valve 16 envelope and blowing through the straw 18. Following inflation, the straw 18 may be removed and the valve 16 and envelope 12 sealed together as described above. To deflate the envelope 12, insert the straw 18 through the gas passage of the valve 16 and lightly squeeze the envelope 12. The valve 16 is re-sealable. Thus, the envelope 12 may be re-inflated as necessary.

Continuing with FIG. 1, the second end 22 of the envelope 12 contains an active light emitting module 24 that is activated by an activation device 28 operatively coupled to the active light emitting module 24. The active light emitting module 24 is enclosed within a transparent chamber or envelope 20 (hereinafter, transparent envelope 20) that extends into the second end 22 of the envelope 12. The transparent envelope 20, the active light emitting module 24, and the activation device 28 are shown in phantom lines within the second end 22 of the envelope 12. The function of the transparent envelope 20 is to retain the active light emitting module 24 in a stable position at the second end of the envelope 12, whereby the orientation of the light emitting device 50 (See FIG. 6) of the light emitting module 24 is maintained toward the opposite first end 14 of the envelope 12. This orientation provides a uniformly illuminated noisemaker 10, clearly visible from all directions from the longitudinal axis of the illuminated noisemaker 10.

Continuing with FIG. 1, a small portion 26 (an outward end) of the transparent envelope 20 extends from the end 22 of the envelope 12. Further, a “pull tab” end of the activation device 28 extends from the outward end 26 of the transparent envelope 20. The active light emitting module 24 includes a light emitting device (LED) and a battery in an electric circuit, and the activation device 28 for causing the electric circuit to enter an operative state, as will be described hereinbelow. In one embodiment to be described (See FIGS. 5 and 6), the activation device 28 functions as a removable insulator between two parts of the electric circuit that, upon removal, closes the circuit to cause the light emitting device (LED) to become illuminated. In another embodiment to be described (See FIG. 7), the activation device 28 functions to close a single pole, single throw (SPST) switch to close the electric circuit to cause the light emitting device (LED) to become illuminated.

Referring to FIG. 2 there is illustrated an enlarged view of a first end of the embodiment of FIG. 1 depicting structures of the inflating mechanism. Shown are the envelope 12 and its first end 14, the inflation device or valve 16, and the removable inflation tube or straw 18. It will be observed that the valve 16 is formed of a first 30 and second 32 layer of the polyethylene film, which may be hot-sealed together along the lines 34. The first layer 30 extends slightly past the second layer 32 to enable grasping the layers when preparing to inflate the envelope 12. An indicating mark 36 imprinted on the surface of the valve 16 may be included to indicate the location of the gas passage between the first 30 and second 32 layers of the valve 16. An arrow 38 may be included to indicate the direction of insertion of the straw 18 or the direction air is to be introduced into the envelope 12. During manufacture, the valve 16 is positioned as shown in the figure and the envelope 12 and valve 16 bonded together using a hot seal method or other suitable process. The portions of the valve 16 and the indicating mark 36 within the envelope 12 are shown in dashed lines.

Referring to FIG. 3 there is illustrated an enlarged view of a second end of the embodiment of FIG. 1 depicting structures of the illuminating mechanism. Shown are the envelope 12 and its second end 22, the active light emitting module 24, the transparent envelope 20, and the activation device 28 equipped with a “pull” tab. Portions of the transparent envelope 20, the active light emitting module 24, and the activation device 28 are shown in phantom lines within the second end 22 of the envelope 12. A small portion 26 (an outward end) of the transparent envelope 20 extends from the end 22. It will be observed that the layers of the envelope 20 may be hot-press sealed together along the lines 44 to better retain the active light emitting module therewithin. During manufacture, the transparent envelope 20 is positioned as shown in the figure and the envelope 12 and transparent envelope 20 bonded together using a hot-press seal or other suitable method along the line 42. The portions of the transparent envelope 20, the active light emitting module 24 within the envelope 12 are shown in dashed lines.

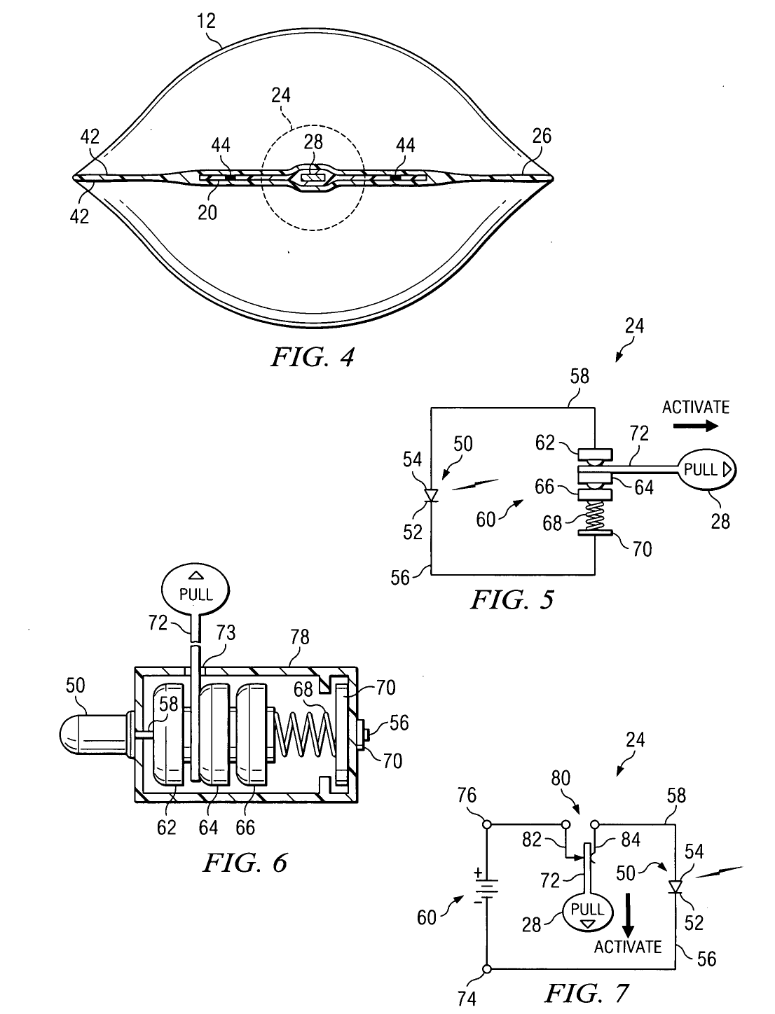

Referring to FIG. 4 there is illustrated a cross section view of the second end of the embodiment of FIG. 3, inflated for use, taken along the line IV-IV. This view of the second end 22 of the envelope 12 represents the appearance of the inflatable noisemaker at or just after sealing of the gas passage in the valve 16 at the first end 14 of the envelope 12. Also shown in FIG. 4 are the phantom-lined outline of the active light emitting module 24 and the actuating device 28 in position prior to activating the light emitting module 24, disposed between the first and second layers of the transparent envelope 20, which may be sealed together along the lines 44 using a hot-press or other suitable method.

Referring to FIG. 5 there is illustrated a pictorial circuit diagram of one embodiment of an active light emitting module 24 for use in the embodiment of FIG. 1. The circuit is a series combination of a light emitting device 50, a battery 60, a compression spring 68, and a metal washer 70. The light emitting device (LED) 50 may be a light emitting diode having a cathode 52 coupled to a first (cathode) lead 56 and an anode 54 coupled to a second (anode) lead 58. The cathode lead 56 is connected to the metallic washer 70 and the anode lead 58 is connected to the positive terminal of a first small button cell 62, one of a plurality of button cells that together provide a battery 60 having sufficient voltage to energize the light emitting device 50. The metallic washer 70 is connected to the compression spring 68, which in turn is connected to a negative terminal of a third (in the illustrated embodiment) small button cell 66.

Inserted between the negative terminal of the first button cell 62 and the positive terminal of a second small button cell 64 is an internal end of the activating device 28. The activating device 28 may be formed of an insulating material approximately 5 to 15 mills thick, thus forming a removable insulating strip that separates the first 62 and second 64 cells. It should be readily apparent to persons skilled in the art that the circuit of the active light emitting module 24 forms a series circuit of an LED 50, a three-cell battery assembly 60, and an activating device 28, which, when the external end of the activating device 28 is pulled away from the three cell battery 60, permits the cells 62 and 64 to contact each other in the manner of switch contacts to complete the electric circuit and cause the LED 50 to become illuminated. The removable insulating strip or activating device 28 may be formed of a length of polyethylene ribbon with a “pull” tab attached to facilitate removal.

Referring to FIG. 6 there is illustrated a pictorial diagram of the one embodiment of the active light emitting module shown in FIG. 5, in which the components of the electric circuit are assembled in a battery holder or cylindrical housing 78 formed of a pair of half shells. A half shell in the illustrated embodiment is defined as a portion of a hollow cylinder cut lengthwise along the longitudinal axis of the cylinder and across the diameter of the cylinder through the full length of the cylinder. The half shells of the housing 78 may be molded of polystyrene or other thermoplastic material according to particular requirements of the application. In the figure, one of the half shells of the housing 78 is removed to show the arrangement of the components of the electric circuit for the active light emitting module 24.

The housing 78 of the active light emitting module 24 preferably includes a window 73 through which the internal end of the activating device 28 passes. The three button cells 62, 64, and 66 are stacked together in a line with the compression spring 68 and the metallic washer 70. A portion of the metal washer may be extended through the end of the housing 78 to enable connection of the cathode lead 56 thereto as shown. The LED 50 is shown adjacent the outer side of the opposite end of the housing 78, wherein the anode lead 58 is shown in contact with the positive terminal of the first cell 62. Upon assembly as described, the removed half shell is replaced, thus enclosing the components of the electric circuit. A resilient sleeve (not shown, as such a device—even a small rubber band—is well understood by persons skilled in the art.) or other similar component may then be slipped over the assembled housing to secure the half shells together. It should be apparent that, as the removable insulating strip 28 is withdrawn through the window 73 when pulled, the compression spring 68 biases the three cells together, completing the electric circuit. This action activates the circuit, causing the LED 50 to illuminate. In an embodiment that employs a resilient sleeve covering the housing 78, a window opening in the resilient sleeve at the position of the window 73 of the housing 78 may be needed to allow passage of the removable insulating strip 28.

Referring to FIG. 7 there is illustrated a circuit diagram of an alternate embodiment of an active light emitting module 24 for use in the embodiment of FIG. 1. The electric circuit is essentially the same as shown in FIG. 5 except that a single pole, single throw (SPST) switch having normally closed (NC) contacts is inserted in the series circuit, and the removable insulating strip placed between the contacts of the switch instead of between two of the battery cells. This alternate construction is better suited to applications where a single cell is used as a battery 60.

The circuit of FIG. 7 is a series combination of an LED 50 having a cathode 52 and anode 54, a battery 60 having a negative terminal 74 and a positive terminal 76, and an SPST switch 80 having a first 82 and a second 84 contacts. The first contact 82 is connected to the positive terminal 76 of the battery 60. The anode 54 of the LED 50 is connected to the second contact 84 of the switch 80 through a lead 58. The cathode 52 of the LED 50 is connected to the negative terminal 74 of the battery 60 through a lead 56. Inserted between the first 82 and second 84 contacts of the switch 80 is the removable insulating strip or activating device 28, which is operated in the same manner as in the previously described embodiment. Pulling the activating device at the “pull” tab permits the first and second contacts 82, 84 to close, completing the electric circuit to illuminate the light emitting device or LED 50.

As in the previous embodiment of the electric circuit for the active light emitting module 24, the illumination will continue until the battery 60 is drained of its energy. Although this is the intended use in the illuminated noisemaker of this type, persons skilled in the art will understand that replacing the activating device 28 shown in the accompanying figures with an actuating device that enables the switch 80 to be turned OFF as well as ON would provide a reusable noisemaker and extend the life of the battery 60.

While the invention has been shown in only one of its forms, it is not thus limited but is susceptible to various changes and modifications without departing from the spirit thereof. The illustrated embodiment is described to demonstrate the principles of the invention. Variations are certainly contemplated, such as replacing the removable insulating strip or activating device 28 with a switch having an actuator that enables both an ON and an OFF mode. Different battery arrangements, multi-cell or single cell may be used, which may dictate the type of switch or activating device is used in the circuit. The light emitting device may preferably be a solid state unit such as a light emitting diode, because of its low power requirements and low emission of heat during operation. In some applications it may be desirable to employ several light emitting devices of different colors, for example, or for providing a greater light output than is provided by a single LED. Further, other types of LEDs—light emitting devices—incandescent, gas-filled, electro-luminescent, etc. may be used in some applications. It should be pointed out, however, that the choice of components depends on the application, and the circuit employed, including the light emitting device, should be one that does not generate or dissipate much heat within the enclosed space of the envelope 20 (See FIGS. 1 and 3).

What is claimed is:

1. An inflatable noisemaker, comprising:
a tubular envelope constructed to enclose a gas under pressure and having a sealable opening for inflating the envelope;
an active light emitting module disposed within the envelope; and
an activation device operatively coupled to the active light emitting module.

2. The noisemaker of claim 1, wherein:
the tubular envelope comprises a flexible, thin-walled tube having first and second ends and fabricated of a plastic membrane sealed at each first and second end.

3. The noisemaker of claim 1, wherein the sealable opening comprises:
an inflation device positioned along a sealed border of the envelope.

4. The noisemaker of claim 3, wherein the inflation device comprises:
a re-sealable seam disposed along a defined portion of the sealed border of the envelope; and
a gas passage defined through the defined portion of the re-sealable seam.

5. The noisemaker of claim 4, wherein the gas passage further comprises:
a removable tube having a diameter sized for inserting through the defined portion of the re-sealable seam.

6. The noisemaker of claim 3, wherein the inflation device includes a sealable inflation tube.

7. The noisemaker of claim 6, wherein the sealable inflation tube comprises a tube having a releasable check valve.

8. The noisemaker of claim 1, wherein the active light emitting module comprises:
at least first and second cells stacked in series polarity, wherein the stacked cells include a negative terminal at one end and a positive terminal at the opposite end of the stacked cells;
a removable insulating strip disposed between the first and second cells and extending away from the stacked cells;
a light emitting device (LED) having cathode and anode leads, wherein the cathode lead of the LED is coupled to a negative terminal of the stacked cells and the anode lead is coupled to a positive terminal of the stacked cells; and
a housing including a spring for biasing the LED, the cells, and the insulating strip together.

9. The noisemaker of claim 8, wherein the removable insulating strip comprises:
a length of polyethylene ribbon having a pull tab portion attached thereto.

10. The noisemaker of claim 8, wherein the housing comprises:
first and second cylindrical half-shells having a first window in one shell for pulling the insulating strip there through; and
a resilient sleeve, having a second window aligned with the first window, for securing the first and second half-shells together as a cylindrical housing.

11. The noisemaker of claim 1, wherein the active light emitting module comprises:
a battery having first and second terminals;
a light emitting device (LED) having first and second leads, wherein the first lead of the LED is connected to the second terminal of the battery; and
an activation device connected between the second lead of the LED and the first terminal of the battery.

12. The noisemaker of claim 11, wherein the LED comprises at least one light emitting diode.

13. The noisemaker of claim 11, wherein the LED comprises at least one light emitting element selected from the group consisting of light emitting diode, an incandescent light bulb, a gas-filled light bulb, and an electro-luminescent light emitter.

14. The noisemaker of claim 11, wherein the activation device comprises:
a single pole, single throw (SPST) switch having normally closed (NC) first and second contacts.

15. The noisemaker of claim 14, further comprising an insulating pull-out tab disposed between the NC contacts of the SPST switch.

16. The noisemaker of claim 14, further comprising an actuator for actuating the NC contacts.

17. The noisemaker of claim 1, wherein the active light emitting module is enclosed within a transparent chamber within the tubular envelope.

18. The noisemaker of claim 1, wherein the active light emitting module comprises:
a battery holder open on one side, having first and second inside ends, and a compression spring disposed in the holder against a first inside end of the holder;
at least first and second cells stacked in the holder in series polarity between the compression spring and the second inside end of the holder, wherein the stacked cells have a negative terminal at one end and a positive terminal at the opposite end;
a removable insulating strip disposed between the first and second cells and extending through the open side of the holder; and
a light emitting device (LED) having cathode and anode leads, wherein the cathode lead of the LED is coupled to the negative terminal and the anode lead is coupled to the positive terminal.

19. The noisemaker of claim 14, further comprising a housing for enclosing the light emitting module comprising:
first and second cylindrical half-shells having a first window in one shell for pulling the insulating strip there through; and
a resilient sleeve, having a second window aligned with the first window, for securing the first and second half-shells together as a cylindrical housing.

20. An inflatable noisemaker, comprising:
a tubular, flexible envelope having first and second ends and constructed to enclose a gas under pressure and further having a sealable opening disposed proximate the first end for inflating the envelope; and
an active light emitting module enclosed within a transparent chamber disposed within the envelope and configured with an activation device.
